(19) United States
(12) Patent Application Publication
(10) Pub. No.: US 2023/0087283 A1
(43) Pub. Date: Mar. 23, 2023

(54) DYNAMIC SENSOR DATA COLLECTION

(71) Applicant: Atieva, Inc., Newark, CA (US)

(72) Inventors: Aijue Liu, Sunnyvale, CA (US); Vivian Huizhi Hou, San Jose, CA (US)

(21) Appl. No.: 17/448,111

(22) Filed: Sep. 20, 2021

(51) Int. Cl. H02J 7/00; G01R 31/3835; G01R 31/392; G01R 31/396

(52) U.S. Cl. CPC H02J 7/0047; H02J 7/0014; G01R 31/3835; G01R 31/392; G01R 31/396; H02J 7/0029

(57) ABSTRACT

A method for managing a battery pack includes making a first voltage reading using a first voltage sensor and a second voltage reading using a second voltage sensor at a voltage measurement point in a battery unit of the battery pack, determining if each of the first voltage reading and the second voltage reading is an in-range reading of voltages in a specified normal voltage range or an out-of-range reading of voltages outside the specified normal voltage range, and based on the determining, characterizing an operational state of the battery unit.

### TECHNICAL FIELD

This document relates to battery packs for electric vehicles.

### BACKGROUND

Battery-operated electric vehicles (EVs) have been implemented in different types. Some are in the form of off-road vehicles such as tugs, tractors, lawn mowers, and golf carts and are associated with short range driving. Also, battery-operated EVs (e.g., consumer cars, long haul trucks, etc.) for on-road or highway use are being introduced or tried out in the marketplace. Widespread adoption of battery-operated EVs for longer-range driving may be affected by concerns about the reliability of the battery packs used to power electric motors in the EVs.

### SUMMARY

In a general aspect, a system includes a battery management system (BMS) coupled to a battery pack. The battery pack includes a plurality of battery cells arranged in one or more modules as groups of battery cells in parallel. The modules are connected to each other in series in a battery circuit. The battery cells have a pre-defined normal voltage range in normal battery operation.

In an aspect, the system includes a plurality of voltage sensors including pairs of voltage sensors. Each pair of voltage sensors is associated with a respective module and includes a first voltage sensor configured to make a first voltage reading at a measurement point in the respective module, and a second voltage sensor configured to make a second voltage reading at the measurement point in the respective module.

In a further aspect, the BMS is configured to collect and process the first voltage readings and the second voltage readings made by the pairs of voltage sensors to manage operation of the battery pack.

In a general aspect, a method for managing a battery pack includes making a first voltage reading using a first voltage sensor and a second voltage reading using a second voltage sensor at a voltage measurement point in a battery unit of the battery pack, determining if each of the first voltage reading and the second voltage reading is an in-range reading of voltages in a specified normal voltage range or an out-of-range reading of voltages outside the specified normal voltage range, and based on the determining, characterizing an operational state of the battery unit.

In a general aspect, a method for managing operation of battery pack includes deploying a plurality of voltage sensors in the battery pack. The plurality of voltage sensors includes pairs of voltage sensors, with each pair of voltage sensors being associated with a respective module. Each pair of voltage sensors includes a first voltage sensor configured to make a first voltage reading at a measurement point in the respective module, and a second voltage sensor configured to make a second voltage reading at the measurement point in the respective module.

In a further aspect, the method includes making first and second voltage readings using the pairs of voltage sensors, and collecting and processing the first voltage readings and the second voltage readings made by the pairs of voltage sensors to manage operations of the battery pack.

### BRIEF DESCRIPTION OF DRAWINGS

FIG. 1 schematically shows an example system with at least two sets of voltage sensors disposed in a battery pack.

FIG. 2 is flowchart illustrating an example method for processing voltage sensor data in a battery management system of a battery pack.

FIG. 3 is flowchart illustrating another example method for processing voltage sensor data in a battery management system

FIG. 4 illustrates an example method for managing a battery pack.

FIG. 5 illustrates another example method for managing a battery pack.

Like reference symbols in the various drawings indicate like elements.

### DETAILED DESCRIPTION

Systems and methods for more reliably predicting battery failure as distinct from predicting individual voltage sensor failure in a battery pack are disclosed herein.

In example implementations, a battery pack may power an electric vehicle (EV) (or other device or tool). The battery pack may, for example, include rechargeable battery cells that are based on lithium-ion electro chemistries.

The battery pack can include individual battery cells and/or groups of individual battery cells organized in series and parallel in an electrical power circuit (battery circuit). The operational conditions, characteristics, and parameters of the battery pack may, for example, include voltage states of the individual battery cells and/or groups of the individual battery cells (hereinafter “battery units”) in the battery circuit. The voltage states of the battery units in normal battery operations (e.g., battery recharging or discharging) may be within a known voltage range (e.g., in a range of 2 volts to 4.4 volts).

An out-of-range voltage state (i.e., with voltages outside the known normal range) of a battery unit may be, in some instances, indicative of a defective or failing battery unit.

The voltage states of the battery units may be measured periodically at measurement locations (hereinafter measurement points) in the battery circuit using voltage sensors that may be incorporated in the battery pack. The measurement points may be associated with the battery units (i.e., the individual battery cells or groups of individual battery cells). In example implementations, the voltage sensors incorporated in the battery pack may be solid state devices or integrated circuits attached to the battery units. Further, the voltage sensors may be either resistive voltage sensors or capacitive voltage sensors.

The voltage sensors may be configured to measure the voltage states at each measurement point periodically, for example, at a frequency in a range of about one hertz to a few kilohertz. In normal battery operation, the voltages at each measurement point may be expected to lie within a range of voltages (e.g., between 2 volts to 5 volts). In some instances, an out-of-range voltage measurement may relate to a battery condition (e.g., a defective or failing battery unit). In other instances, an out-of-range voltage measurement may relate to a more common occurrence of a voltage sensor failure (e.g., due to a loose connection wire, etc.).

A battery management system (BMS) (e.g., an electronic system) may be coupled to the battery pack. The BMS may be configured to gather and monitor information about battery operating conditions, including, for example, one or more of voltage, current, and temperature of battery units in the battery. The BMS may protect the battery from operating outside safe operating areas, for example, by monitoring the battery's operational state, calculating and reporting secondary data, controlling the battery's environment, authenticating and/or balancing the battery cells during battery operation.

In example implementations, for a battery pack in an EV, vehicle safety considerations (including a need to mitigate a risk of catastrophic battery failure such as a fire) require that upon any indication of out-of-range operation of a battery cell or group, the battery pack should be promptly disabled (e.g., even in a moving EV), and removed from service for further inspection, repair, or replacement. Even if the out-of-range voltage measurement does not actually relate to a battery condition, but instead relates to the more common occurrence of voltage sensor failure, a traditional BMS may, based on the vehicle safety considerations, require disengaging or removal of the battery pack from service immediately for further inspection, repair or replacement. This safety requirement, because of the time that may be involved in inspection, repair or replacement of the battery packs, can handicap use of battery packs in EVs, and severely hamper or hinder widespread adoption of EVs (e.g., for transportation).

In example implementations, the disclosed systems and methods for more reliably predicting battery failure as distinct from individual voltage sensor failure involve deploying two sets of parallel or complimentary voltage sensors (i.e., a first set of voltage sensors and a second set of voltage sensors) to make voltage measurements in the battery units of a battery pack. The two sets of parallel or complimentary voltage sensors can make duplicate voltage measurements, about or nearly simultaneously or concurrently, at the measurement points in the battery units of the battery pack. The voltage measurement at a measurement point associated with a battery unit by a voltage sensor from the first set of voltage sensors may be referred to herein as a first or primary voltage measurement at the measurement point associated with the battery unit. The voltage measurement at the measurement point by a voltage sensor from the second set of voltage sensors may be referred to herein as a second or secondary voltage measurement at the measurement point.

In example implementations, the BMS may be configured to process primary voltage measurements (made by voltage sensors from the first set of voltage sensors), when processing information about battery operating conditions to manage battery operations.

In example implementations, the BMS may be configured to process a single out-of-range voltage measurement by a voltage sensor (e.g., a primary voltage sensor) as a measurement that needs to be verified or confirmed to determine whether the single measurement is indicative of a defective or failing battery unit, or is merely indicative of a voltage sensor failure. For verification or confirmation, the BMS may evaluate a secondary voltage measurement made by the secondary voltage sensor at the same measurement point at about the same time (i.e., simultaneously or concurrently) as the measurement made by the primary voltage sensor.

If the secondary voltage measurement is an in-range voltage measurement, the BMS may process the out-of-range primary voltage measurement not as being indicative of a defective or failing battery unit, but merely as being indicative of a voltage sensor failure. The BMS may replace the out-of-range primary voltage measurement by the in-range secondary voltage measurement when processing information on the battery's operating conditions to manage battery operations.

If the secondary voltage measurement is also an out-of-range voltage measurement (like the out-of-range primary voltage measurement), the BMS may recognize the out-of-range primary voltage measurement (and the out-of-range secondary voltage measurement) as being a confirmed incident of a defective or failing battery unit. The BMS may flag the battery unit associated with the out-of-range primary and secondary voltage measurements for remedial action (e.g. for disengagement, inspection, repair or replacement, etc.).

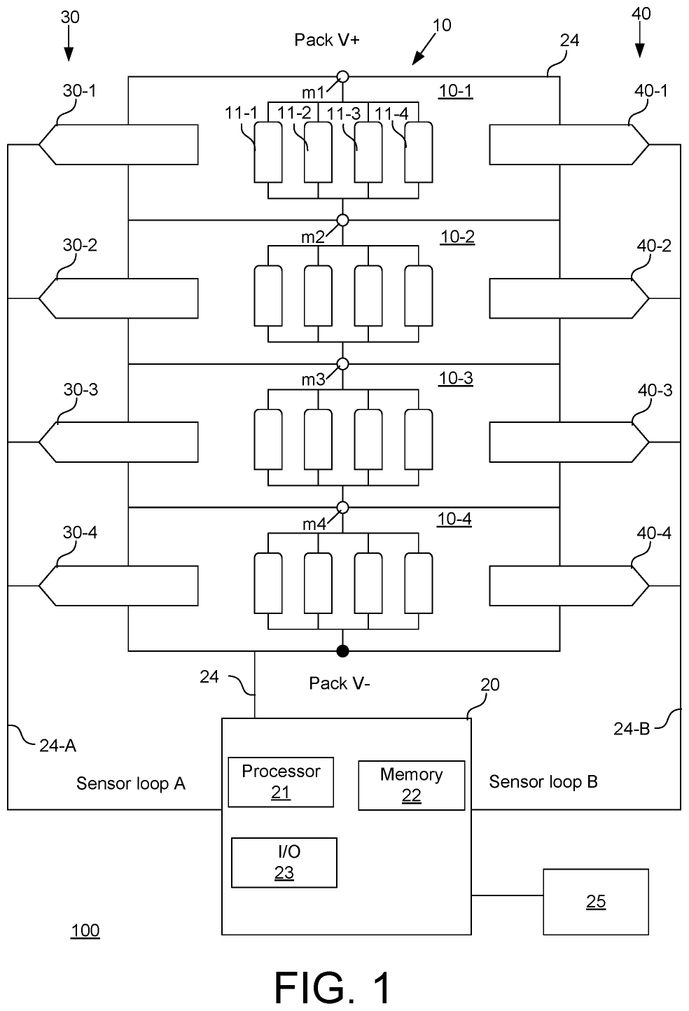

FIG. 1 schematically shows an example system 100 with at least two sets of voltage sensors disposed in a battery pack. System 100 may be configured for distinguishing incidents of out-of-range battery operation from incidents of voltage sensor failure in the battery pack. Any or all other examples described herein can be combined with, and/or performed in, the system 100.

System 100 includes a battery management system (BMS) 20 coupled to battery pack 10. A first set of voltage sensors 30 and a second set of voltage sensors 40 may be incorporated in battery pack 10 to measure voltages in the battery pack to monitor battery operation. BMS 20 may process information including the measured voltage readings to manage battery operations.

In example implementations, battery pack 10 may, for example, be a rechargeable battery based on Li-ion electro chemistry, and intended for use, for example, in EV applications. Battery pack 10 may include any number of individual battery cells (e.g., battery cell 11-1, 11-2, 11-3, and 11-4, etc.) distributed as individual battery cells or in groups in battery units of the battery pack. The battery cells may, for example, be Li-ion batteries, each with an output maximum voltage rating of, for example, greater than or equal to 4.1 volts. Battery pack 10 may have any topology of the battery cells, with the individual battery cells being connected in parallel and/or in series. For example, battery pack 10 may include several modules (e.g., modules 10-1, 10-2, 10-3, and 10-4, etc.) connected in series, with each module containing a group of battery cells (e.g., battery cells 11-1, 11-2, 11-3, and 11-4, etc., for the module 10-1) connected in parallel.

First set of voltage sensors 30 may include individual voltage sensors (e.g., first or primary voltage sensors 30-1, 30-2, 30-3, and 30-4, etc.) that may be arranged to measure the voltages at respective measurement locations or points (e.g., measurements points m1, m2, m3, and m4, etc.) in the several modules (e.g., module 10-1, 10-2, 10-3, and 10-4, etc.). Second set of voltage sensors 40 may include individual voltage sensors (e.g., second or secondary voltage sensors 40-1, 40-2, 40-3, and 40-4, etc.) that may be arranged in parallel to the first set of voltage sensors 30 to measure the voltages at same respective measurement points (e.g., measurements points m1, m2, m3, and m4, etc.) in the several modules (e.g., module 10-1, 10-2, 10-3, and 10- 4, etc.). In other words, the voltage sensors may be arranged so that the voltages at each measurement point (e.g., measurement point m1) in the several modules can be almost concurrently or simultaneously measured by two sensors—a first voltage sensor (e.g., primary voltage sensor 30-1) from the first set of voltage sensors 30, and a second voltage sensor (e.g., secondary voltage sensor 40-1) from the second set of voltage sensors 40.

In the example instance shown in FIG. 1, the battery cell topology of battery pack 10 includes, only for purposes of illustration, an example of a total of sixteen individual battery cells distributed across four modules (i.e., modules 10-1, 10-2, 10-3, and 10-4) in series. Each module contains four battery cells (i.e., battery cell 11-1, 11-2, 11-3, and 11-4) in parallel. In other examples of battery cell topology, battery pack 10 may include a different total number (e.g., 2 to 200) of individual battery cells, a different number (e.g., 1 to 20) of modules in series, and each of the modules may include a different number (e.g., 1 to 50) battery cells connected in parallel.

BMS 20 may be coupled to battery pack 10 and the sets of voltage sensors 30 and 40 via a battery circuit 24. In example implementations, the set of voltage sensors 30 may be connected to BMS 10 on a first sensor loop (e.g., sensor loop A, 24-A), and the set of voltage sensors 40 may be connected to BMS 10 on a second sensor loop (e.g., sensor loop B, 24-B).

BMS 20 may protect battery pack 10 from operating outside safe operating areas, for example, by monitoring the battery's operational state, calculating and reporting secondary data, disconnecting battery from electrified powertrain, and controlling the battery's operating conditions.

In example implementations, BMS 20 may include, for example, at least one processor (e.g., processor 21), a memory (e.g., memory 22), and input/output (I/O) unit (e.g., I/O unit 23). I/O unit may be connected (e.g., by wire or wirelessly) to external device 25. External device 25 may, for example, include devices or circuits (e.g., power switches, battery charging and discharging circuits, battery cell balancing circuits, displays, user interfaces, etc.) (not shown) that may be used to control or manage battery operations. Processor 21 may be configured to execute instructions stored in memory 22 to, for example, collect information about the battery operating conditions, including, for example, the voltages at the measurement points (e.g., measurements points m1, m2, m3, and m4, etc.) in the several modules (e.g., module 10-1, 10-2, 10-3, and 10-4, etc.). The voltages at the measurement points may include voltages measured by the voltage sensors (of the first set of voltage sensors 30 and or the second set of voltage sensors 40).

BMS 20 may include algorithms configured to recognize a first out-of-range voltage measurement (e.g., a voltage reading outside a nominal normal range) at a measurement point (e.g., measurement point m3) as an indication of a fault (e.g., a sensor failure, or a battery unit failure) associated with the measurement point. An example nominal normal range for a Li-ion battery (used in EV applications) may, for example, be from 2.0 volts to 4.4 volts. The first out-of-range voltage measurement may, for example, be a voltage reading >4.4 volts or <2.0 volts. The first out-of-range voltage measurement may be a voltage measurement made either by a voltage sensor (e.g., voltage sensor 30-3) from the first set of voltage sensors 30 or a voltage sensor (e.g., voltage sensor 40-3) from the second set of voltage sensors 40.

BMS 20 may further include algorithms configured to further characterize the fault associated with the measurement point (e.g., measurement point m3) as being a battery unit failure, or merely a voltage sensor failure. The algorithms may compare the voltage measurement readings made concurrently at the measurement point by a voltage sensor (e.g., sensor 30-3) from the first set of voltage sensors 30 and a voltage sensor (e.g., sensor 40-3) from the second set of voltage sensors 40.

If both voltage sensor readings (e.g., made by sensor 30-3 and sensor 40-3) are out-of-range, BMS 20 may identify the fault associated with the measurement point (e.g., measurement point m3) as likely being a battery unit failure (e.g., a failure of battery module 10-3). Based on safety considerations, BMS 20 may initiate appropriate remedial actions to immediately disable, repair, or replace, battery pack 10.

If only one of the two voltage sensor readings is an out-of-range reading, BMS 20 may identify the fault associated with the measurement point (e.g., measurement point m3) as merely being a voltage sensor failure. BMS 20 may flag or schedule the voltage sensors for maintenance repair or service, but may not take any immediate actions to disable or replace battery pack 10.

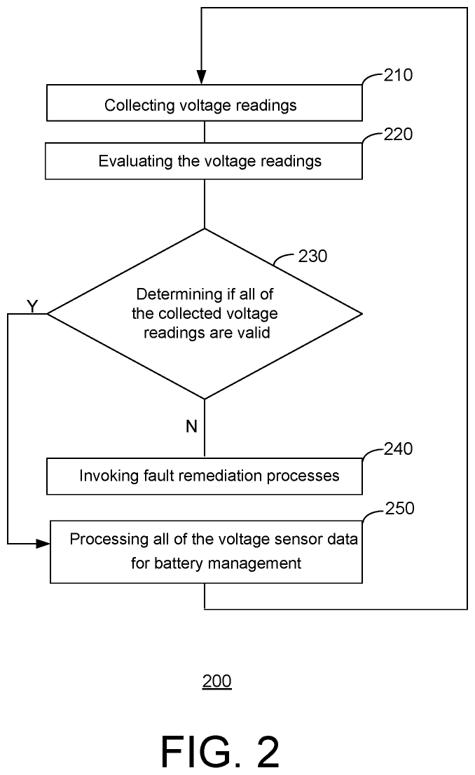

FIG. 2 is a flowchart illustrating an example method 200 for processing voltage sensor data in a battery management system (e.g., BMS 20) of a battery pack (e.g., battery pack 10). Method 200 may be implemented, for example, in system 100 (FIG. 1) in which voltage measurement points are identified for one or more battery units (e.g., an individual battery cell, or a group of battery cells connected in parallel) of the battery pack, and in which at least a pair (i.e., at least two) voltage sensors are deployed to measure voltages at each of the voltage measurement points in the battery pack.

Method 200 includes collecting voltage readings (210), and evaluating the voltage readings (220). Collecting voltage readings 210 may include collecting pairs of voltage readings made by respective pairs of voltage sensors at each of the voltage measurement points in the battery pack. Each pair of voltage sensors may include a first voltage sensor (i.e., a primary voltage sensor) and second voltage sensor (i.e., a secondary voltage sensor). Each pair of voltage readings may be made about the same time (i.e., about simultaneously or concurrently) by each of the voltage sensors in the respective pair of voltage sensors deployed to measure voltages at the voltage measurement points. Evaluating the voltage readings 220 may include evaluating whether each of the collected voltage readings is within or outside a normal voltage range corresponding to normal battery operations (e.g., charging, holding, or discharging operations). A normal voltage range for a voltage reading may be predefined based on the type or types of battery cells used in battery pack 10. For a Li-ion battery cell, the normal range may, for example, be between 2.0 volts and 4.4 volts.

Method 200 may further include determining if all of the collected voltage readings are valid ( 230). A voltage reading may be valid if it is within the normal voltage range expected for normal battery operations (e.g., between 2.0 volts and 4.4 volts, for Li-ion battery cells). If all of the of the collected voltage readings are determined to be valid at 230, method 200 may include processing all of the voltage sensor data for battery management (250). The voltage sensor data processed for battery management may, for example, include the validated collected voltage readings, locations of the measurement points, and identifications of the associated battery units (e.g., battery cells and/or battery modules), etc. The battery management system may use this voltage sensor data for implementing one or more battery management functions including, for example, battery cell balancing, discharging, and recharging, etc.

If at step 230, in method 200, any one of the collected voltage readings is determined to be invalid or abnormal (i.e., not in the normal voltage range of battery operation), method 200 may include invoking a fault remediation processes (240). The fault remediation processes implemented by the battery management system may include disengaging (e.g., switching off), discharging, removal, repair or replacement of the battery pack.

In example implementations, under method 200, the fault remediation processes may be invoked at 240 regardless of which of the pair of the two voltage sensors (e.g., sensor 30-3 and sensor 40-3, FIG. 1) deployed to measure voltages has generated the invalid voltage reading at the voltage measurement point (e.g., measurement point m3, FIG. 1). Further, under method 200, the fault remediation processes may be invoked at 240 without a determination of whether the invalid voltage sensor reading (e.g., by either sensor 30-3 and sensor 40-3, FIG. 1) is a voltage sensor failure or a battery cell failure. The method does not necessarily distinguish voltage sensor failures from battery cell failures. Based on safety considerations (discussed previously), all faults may be treated as if they are battery cell failures. Any invalid voltage sensor reading is treated as if it is a battery cell failure, at least in EV uses of the battery.

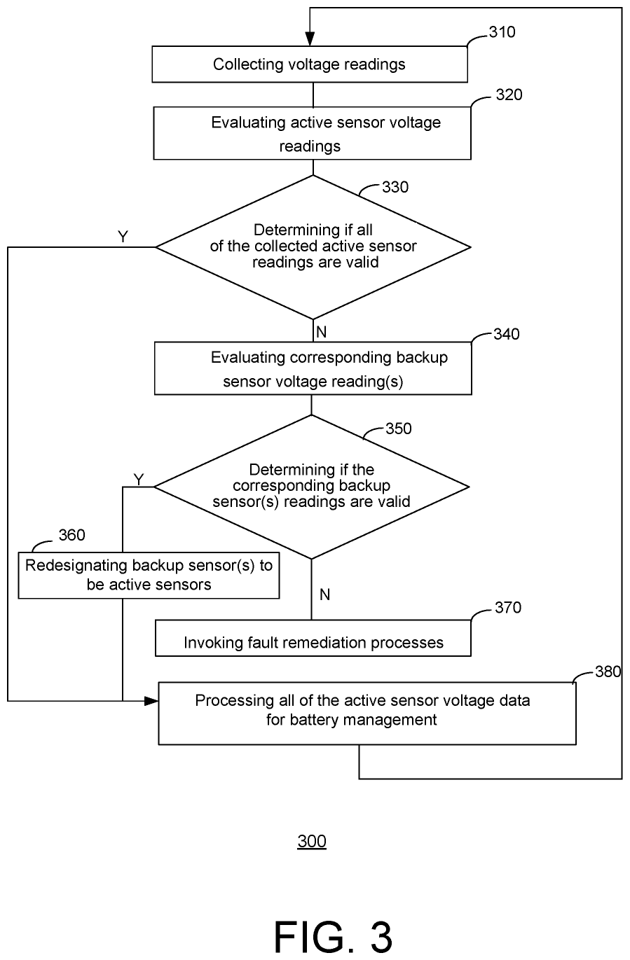

FIG. 3 is flowchart illustrating another example method 300 for processing voltage sensor data in a battery management system (e.g., BMS 20) of a battery pack (e.g., battery pack 10). Like method 200, method 300 may be implemented, for example, in system 100 (FIG. 1) in which voltage measurement locations or points are identified for one or more battery units (e.g., an individual battery cell, or a group of battery cells connected in parallel) of the battery pack, and at least a pair (i.e., at least two) voltage sensors are deployed to measure voltages at each of the voltage measurement points in the battery pack.

In example implementations of method 300, one of the pair of the at least two voltage sensors associated with a measurement point may be designated to be an active (or primary) sensor, while the other of the pair of the at least two voltage sensors may be designated to be a backup (or secondary) sensor. In example implementations of method 300, sensors deployed along a first sensor loop (e.g., voltage sensors 30-1, 30-2, 30-3, and 30-4, etc., deployed on sensor loop A, 24-A, FIG. 1) may be designated to be the active sensors, and the corresponding paired parallel sensors deployed along a second sensor loop (e.g., voltage sensors 40-1, 40-2, 40-3, and 40-4, etc., deployed on sensor loop B, 24-B, FIG. 1) may be designated to be the backup sensors (or vice versa).

Like method 200, method 300 may include collecting voltage readings (310). Collecting voltage readings 310 may include collecting pairs of voltage readings made by respective pairs of active and backup voltage sensors at each of the voltage measurement points in the battery pack.

Method 300 further includes evaluating all active sensor voltage readings (320). Evaluating all active sensor voltage readings 320 may include evaluating if each of the collected active sensor voltage readings is within or outside a normal voltage range corresponding to normal battery operations (e.g., charge holding, discharging or recharging operations). Method 300 may further include determining if all of the collected active voltage readings are valid (330). A voltage reading may be valid if it is within the normal voltage range expected for normal battery operations (e.g., between 2.0 volts and 4.4 volts, for Li-ion battery cells). If all of the of the collected active voltage readings are determined to be valid at 330 (i.e., the active voltage readings are in a normal voltage range), method 300 may include processing all of the active voltage sensor data for battery management (380). The voltage sensor data processed for battery management may, for example, include the validated active voltage sensor readings, locations of the measurement points and identification of the associated battery units (e.g., battery cells and/or battery modules), etc. The battery management system may use this voltage sensor data for implementing one or more battery management functions including, for example, battery cell balancing, discharging and recharging, etc.

In method 300, if at step 330 any one of the collected active sensor voltage readings is determined to be invalid or not in the normal voltage range of battery operations, method 300 may include evaluating the corresponding backup sensor voltage reading(s) (340), and determining if the corresponding backup sensor voltage reading(s) are valid (350). If the corresponding backup sensor voltage reading(s) are determined to be valid at 350 (i.e., the corresponding backup sensor voltage readings are in a normal voltage range), method 300 may include redesignating the corresponding backup sensor(s) to be active sensors (360). Method 300 may include the corresponding backup sensor data redesignated as active voltage sensor data when processing data for battery management at step 380.

If the corresponding backup sensor voltage reading(s) are determined to be invalid at 350 (i.e., the one of the collected active sensor voltage readings and the corresponding backup sensor voltage reading(s) are both invalid, or abnormal), method 300 may treat the occurrence as an instance of battery failure. In response, method 300 may include invoking fault remediation processes 370). The fault remediation processes implemented by the battery management system may include disengaging (e.g., switching off), discharging, removal, repair or replacement of the battery pack.

Voltage sensors incorporated in battery packs may fail, for example, because defects or inconsistencies in manufacturing or assembly processes. In an example scenario, the voltage sensor failures may often be unrelated to defects or failure of the battery cells in the battery packs, but are used as a convenient proxy or indicator of battery failure. Method 200 (FIG. 2) and method 300 (FIG. 3), as discussed above, use quantitatively different voltage sensor failure thresholds as a proxy indicator of battery failure to remove a battery pack from service. The two methods can result in very different expectations for the time that a battery pack can be reliably kept in service without safety concerns (e.g., in an EV application) as illustrated by the following Example.

### EXAMPLE

Consider a battery pack for an EV including 100 parallel groups of battery cells. Each of the 100 groups of battery cells includes voltage sensors to measure voltages of the group of battery cells. Assume that a probability p of one voltage sensor failing in x months is 0.01%. Then, a probability P of having the battery pack deemed to be failing, unreliable, or unsafe in x months using method 200 (with a single voltage sensor failure=battery failure) may be given by:

$$P = 1 - {( 1 - \frac{p}{100} )}^{100} = 1 - {( 1 - 0.0001 )}^{100} = 1. \times {10}^{- 2}$$

In contrast, the probability P of having the battery pack deemed to be failing, unreliable, or unsafe in x months using method 300 (with a pair of voltage sensor failures=battery failure) may be given by:

$$P = 1 - {( 1 - ( \frac{p}{100} ) \times ( \frac{p}{100} ) )}^{100} = 1 - {( 1 - {0.0001}^{2} )}^{100} = 1. \times {10}^{- 6}$$

Clearly, method 300 (using a two-voltage-sensor failure as a threshold to indicate battery failure) results in improved availability of the battery pack by a factor of ten thousand (i.e., 10⁴), which can be significant time factor for EV applications of the battery pack.

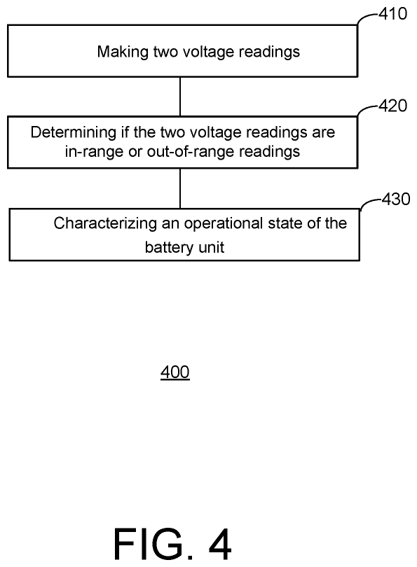

FIG. 4 shows an example method 400 for managing a battery pack. The battery pack includes a plurality of battery units. Each battery unit includes a set of one or more battery cells connected in parallel. The battery units have a pre-defined or specified normal voltage range in normal battery operations. The battery units may include Li-ion cells and may have a specified normal voltage range of about 2.0 volts to 4.4 volts in normal operation.

In example implementations, method 400 includes making two voltage readings (410). The two voltage readings (i.e., a first voltage reading and a second voltage reading) may be at a voltage measurement point in a battery unit. The two voltage readings may be made at about the same time (i.e., simultaneously or concurrently) using a first voltage sensor and a second voltage sensor, respectively.

Method 400 further includes determining if the two voltage readings are in-range or out-of-range readings (420). Determining if the two voltage readings are in-range or out-of-range readings involves determining if each of the two voltage readings is an in-range reading of voltages inside the specified normal voltage range, or an out-of-range readings of voltages outside the specified normal voltage range. Method 400 further includes, based on the determining, characterizing an operational state of the battery unit (430).

Characterizing the operational state of the battery unit 430 includes characterizing the operational state of the battery unit as one of battery failure when both of the two voltage readings are out-of-range voltage readings, or characterizing the operational state of the battery unit as one of voltage sensor failure when only one of the two voltage readings is an out-of-range voltage reading.

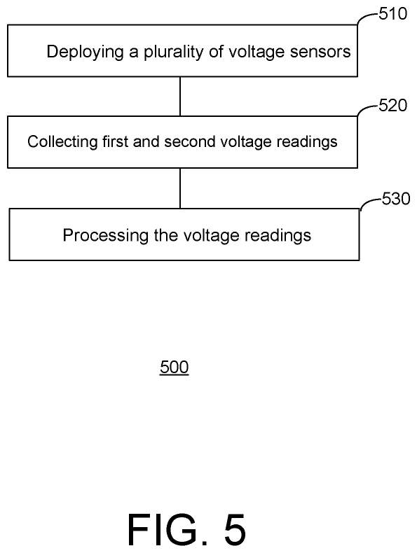

FIG. 5 shows another example method 500 for managing a battery pack. The battery pack includes a plurality of battery units. Each battery unit includes a set of one or more battery cells connected in parallel. The battery units have a specified normal voltage range in normal battery operations. The battery units may include Li-ion cells and may have a specified normal voltage range of about 2.0 volts to 4.5 volts in normal operation.

Method 500 deploying a plurality of voltage sensors (510). The plurality of sensors may include pairs of voltage sensors deployed in the battery pack. Each pair of voltage sensors may be associated with a respective battery unit, and each pair may include a first voltage sensor configured to make a first voltage reading at a measurement point in the respective battery unit, and a second voltage sensor configured to make a second voltage reading at the measurement point in the respective battery unit.

Method 500 further includes collecting first and second voltage readings (520), and processing the voltage readings (530). The voltage readings processed may include first voltage readings and second voltage readings made by the pairs of voltage sensors at measurement points in the battery units. Processing the voltage readings 530 may include managing operations of the battery pack.

Processing the voltage readings 530 may include characterizing an instance of the first voltage reading and the second voltage reading at the measurement point of a particular module both being out-of-range voltage readings as an instance of battery failure, or characterizing an instance of only one of the first voltage reading and the second voltage reading being an out-of-range voltage reading as an instance of voltage sensor failure.

Processing the voltage readings 530 may include substituting an in-range second voltage reading at the measurement point of a particular module for an out-of-range first voltage reading at the measurement point of the particular module.

Processing the voltage readings 530 may include processing only the in-range first voltage readings and the substitute in-range second voltage readings to manage operations of the battery pack.

Examples herein refer to a battery module, which is an individual component configured for holding and managing multiple electrochemical cells during charging, storage, and use. The battery module can be intended as the sole power source for one or more loads (e.g., electric motors), or more than one battery module of the same or different type can be used. Two or more battery modules can be implemented in a system separately or as part of a larger energy storage unit. For example, a battery pack can include two or more battery modules of the same or different type. A battery module can include control circuitry for managing the charging, storage, and/or use of electrical energy in the electrochemical cells, or the battery module can be controlled by an external component. For example, a battery management system can be implemented on one or more circuit boards (e.g., a printed circuit board).

Examples herein refer to electrochemical cells (i.e., battery cells). An electrochemical cell can include an electrolyte and two electrodes to store energy and deliver it when used. In some implementations, the electrochemical cell can be a rechargeable cell. For example, the electrochemical cell can be a lithium-ion cell. In some implementations, the electrochemical cell can act as a galvanic cell when being discharged, and as an electrolytic cell when being charged. The electrochemical cell can have at least one terminal for each of the electrodes. The terminals, or at least a portion thereof, can be positioned at one end of the electrolytic cell. For example, when the electrochemical cell has a cylindrical shape, one of the terminals can be provided in the center of the end of the cell, and the can that forms the cylinder can constitute the other terminal and therefore be present at the end as well. Other shapes of electrochemical cells can be used, including, but not limited to, prismatic shapes.

The terms “substantially,” “nearly,” and “about” used throughout this Specification are used to describe and account for small fluctuations, such as due to variations in processing or assembly. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail herein (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems. Accordingly, other implementations are within the scope of the following claims.

While certain features of the described implementations have been illustrated as described herein, many modifications, substitutions, changes and equivalents will now occur to those skilled in the art. It is, therefore, to be understood that appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A system comprising:
a battery pack; and
a battery management system (BMS) coupled to the battery pack, the battery pack including:
a plurality of battery cells, the battery cells arranged in one or more modules as groups of battery cells in parallel, the modules being connected to each other in series in a battery circuit, the battery cells having a pre-defined normal voltage range in normal battery operation; and
a plurality of voltage sensors including pairs of voltage sensors, each pair of voltage sensors associated with a respective module, each pair including:
a first voltage sensor configured to make a first voltage reading at a measurement point in the respective module; and
a second voltage sensor configured to make a second voltage reading at the measurement point in the respective module,
the BMS configured to collect and process the first voltage readings and the second voltage readings made by the pairs of voltage sensors to manage operation of the battery pack.

2. The system of claim 1, wherein the BMS determines that the first voltage reading and the second voltage reading at the measurement point of a particular module both being out-of-range voltage measurements is an indicator of battery failure.

3. The system of claim 1, wherein the BMS determines that only one of the first voltage reading and the second voltage reading at the measurement point of a particular module being an out-of-range voltage measurement is an indicator of voltage sensor failure.

4. The system of claim 1, wherein the BMS substitutes an in-range second voltage reading at the measurement point of a particular module for an out-of-range first voltage reading at the measurement point of the particular module.

5. The system of claim 4, wherein the BMS processes only the in-range first voltage readings and the substitute in-range second voltage readings to manage operation of the battery pack.

6. The system of claim 1, wherein the battery cells are Li-ion cells.

7. The system of claim 4, wherein the battery cells have a pre-defined normal voltage range of about 2.0 volts to 4.5 volts in normal operation.

8. The system of claim 1, wherein the plurality of voltage sensors includes a set of first voltage sensors disposed on a first sensor loop and a set of second voltage sensors disposed on a second sensor loop in the battery circuit.

9. A method for managing a battery pack, the battery pack comprising a plurality of battery units, each battery unit including a set of one or more battery cells connected in parallel, the battery units having a specified normal voltage range in normal battery operations; the method comprising:
making a first voltage reading using a first voltage sensor and a second voltage reading using a second voltage sensor at a voltage measurement point in a battery unit;
determining if each of the first voltage reading and the second voltage reading is an in-range reading of voltages in the specified normal voltage range or an out-of-range reading of voltages outside the specified normal voltage range; and
based on the determining, characterizing an operational state of the battery unit.

10. The method of claim 9, wherein characterizing the operational state of the battery unit includes characterizing the operational state of the battery unit as one of battery failure when both the first voltage reading and the second voltage reading are out-of-range voltage readings.

11. The method of claim 9, wherein characterizing the operational state of the battery unit includes characterizing the operational state of the battery unit as one of voltage sensor failure when only one of the first voltage reading and the second voltage reading is an out-of-range voltage reading.

12. The method of claim 9, wherein the battery units include Li-ion cells.

13. The method of claim 12, wherein the battery units have the specified normal voltage range of about 2.0 volts to 4.5 volts.

14. A method for managing operation of battery pack, the battery pack comprising:
a plurality of battery cells, the battery cells arranged in one or more modules as groups of battery cells in parallel, the modules being connected to each other in series in a battery circuit, battery cells having a pre-defined normal voltage range in normal battery operation, the method comprising:
deploying a plurality of voltage sensors in the battery pack, the plurality of voltage sensors including pairs of voltage sensors, each pair of voltage sensors being associated with a respective module, each pair including:
a first voltage sensor configured to make a first voltage reading at a measurement point in the respective module; and
a second voltage sensor configured to make a second voltage reading at the measurement point in the respective module;
making first and second voltage readings using the pairs of voltage sensors; and
collecting and processing the first voltage readings and the second voltage readings made by the pairs of voltage sensors to manage operations of the battery pack.

15. The method of claim 14, wherein the method further includes characterizing an instance of both the first voltage reading and the second voltage reading at the measurement point of a particular module being out-of-range voltage readings as an instance of battery failure.

16. The method of claim 14, wherein the method further includes characterizing an instance of only one of the first voltage reading and the second voltage reading at the measurement point of a particular module being an out-of-range voltage reading as an instance of voltage sensor failure.

17. The method of claim 14, wherein processing the first voltage readings and the second voltage readings made by the pairs of voltage sensors to manage operations of the battery pack includes substituting an in-range second voltage reading at the measurement point of a particular module for an out-of-range first voltage reading at the measurement point of the particular module.

18. The method of claim 14, wherein processing the first voltage readings and the second voltage readings made by the pairs of voltage sensors to manage operations of the battery pack includes processing only the in-range first voltage readings and the substitute in-range second voltage readings to manage operations of the battery pack.

19. The method of claim 14, wherein the battery cells are Li-ion cells.

20. The method of claim 19, wherein the battery cells have the pre-defined normal voltage range of about 2.0 volts to 4.5 volts in normal operation.
